(19) United States
(12) Patent Application Publication
(10) Pub. No.: US 2006/0270166 A1
(43) Pub. Date: Nov. 30, 2006

(54) Laser spike annealing for gate dielectric materials

(76) Inventors: Liang-Gi Yao, Hsinchu (TW); Ming-Ho Yang, Jhubei City (TW); Shih-Chang Chen, Hsin-Chu (TW); Mong Song Liang, Hsin-Chu (TW)

Correspondence Address: SLATER & MATSIL, L.L.P., 17950 PRESTON ROAD, SUITE 1000, DALLAS, TX, 75252, US

(21) Appl. No.: 11/140,766

(22) Filed: May 31, 2005

(51) Int. Cl. H01L 21/336

(52) U.S. Cl. 438/287; 438/591; 438/308

(57) ABSTRACT

A method of forming a semiconductor device using laser spike annealing is provided. The method includes providing a semiconductor substrate having a surface, forming a gate dielectric layer on the surface of the semiconductor substrate, laser spike annealing the gate dielectric layer, and patterning the gate dielectric layer and thus forming at least a gate dielectric. Source and drain regions are then formed to form a transistor. A capacitor is formed by connecting the source and drain regions.

### TECHNICAL FIELD

This invention relates generally to semiconductor devices, specifically to manufacturing processes of semiconductor devices, and more specifically to laser spike annealing of gate dielectrics.

### BACKGROUND

With semiconductors devices increasingly scaled down, gate dielectrics become thinner with thicknesses approaching about 20 Å or less. At such a small dimension, any tunneling through a gate dielectric layer to the underlying channel region significantly increases gate-to-channel leakage current and increases power consumption. Gate dielectrics are therefore required to have high density and fewer pores.

High-k materials are commonly used as gate dielectrics for MOSFET devices. However, high-k materials have a disadvantage that their densities are lower than conventional thermally grown, low-k silicon dioxide. One of the methods of improving density is annealing, by which the material density is increased and thus electrical properties are improved.

Conventionally, gate dielectric annealing is performed by rapid thermal annealing (RTA) or furnace annealing, which requires temperature as high as around 700° C. Since wafers are typically kept at high temperature for a long period, conventional rapid thermal annealing and furnace annealing have drawbacks of agglomeration formation, high thermal budget cost, and high diffusion of impurities. In order to solve these problems, spike annealing, by which temperature is rapidly ramped up to a desired value, and rapidly lowered back, has been developed. Since wafers are kept at high temperature for very short time, the above mentioned problems are significantly reduced.

Laser thermal annealing (LTA) has been recently explored in the semiconductor manufacturing art. A method of annealing gate dielectrics using LTA, as described in U.S. Pat. No. 6,632,729, which is incorporated herein by reference, is illustrated in FIG. 1. The method comprises the steps of forming a gate oxide layer on a substrate 2; forming a gate electrode layer on the gate oxide layer; patterning the gate oxide layer and gate electrode layer and thus forming a gate oxide 4 and a gate electrode 6; forming source/drain regions 10; and laser annealing the gate oxide 4 using laser thermal annealing, which is symbolized by arrows 12. This method can rapidly anneal gate dielectric 4 without causing agglomeration and diffusion. It suffers some drawbacks, however. The laser beam has to travel through the gate electrode 6 before it reaches gate oxide 4. Since gate electrode 6 absorbs laser energy, if not well controlled, the gate electrode may absorb too much energy, causing the gate dielectric to remain below the desired annealing temperature. The energy absorption is particularly severe when the gate electrode is thick. The energy absorption rate in the gate electrode 6 is determined by both material and thickness of the gate electrode; therefore, is hard to reliably determine.

Therefore, there is a need for a reliable method of annealing a gate dielectric with minimum agglomeration, diffusion and thermal budget cost.

### SUMMARY OF THE INVENTION

In accordance with one aspect of the present invention, a method of forming a MOS device having a laser spike annealed dielectric includes the steps of: providing a semiconductor substrate having a surface; forming a gate dielectric layer on at least a portion of the surface of the semiconductor substrate; laser spike annealing the gate dielectric layer; and patterning the gate dielectric layer and thus forming at least a gate dielectric. Since there is no gate electrode layer to absorb the energy of the laser beam, laser beam with lower power rate can be used.

In accordance with another aspect of the present invention, the laser spike annealing can be performed after the formation of a thin gate electrode layer. The thickness of the gate electrode layer is such that enough laser energy penetrates the gate electrode layer without melting it while the temperature in the gate dielectric layer can be raised to desired values.

In accordance with yet another aspect of the present invention, a capacitor is formed by connecting the source and drain of the MOS device. With laser spike annealed gate dielectric, the capacitor has greater capacitance and is less likely to breakdown.

An advantageous feature of the present invention is that the gate dielectric layer can be annealed rapidly without causing agglomeration and diffusion.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a conventional method for annealing a gate oxide using laser thermal annealing;

FIGS. 2 through 6 are cross-sectional views of intermediate stages of an embodiment of the present invention; and

FIG. 7 illustrates carrier mobility as a function of effective electrical field in dielectric materials, wherein comparisons are made between laser spike annealing and thermal annealing.

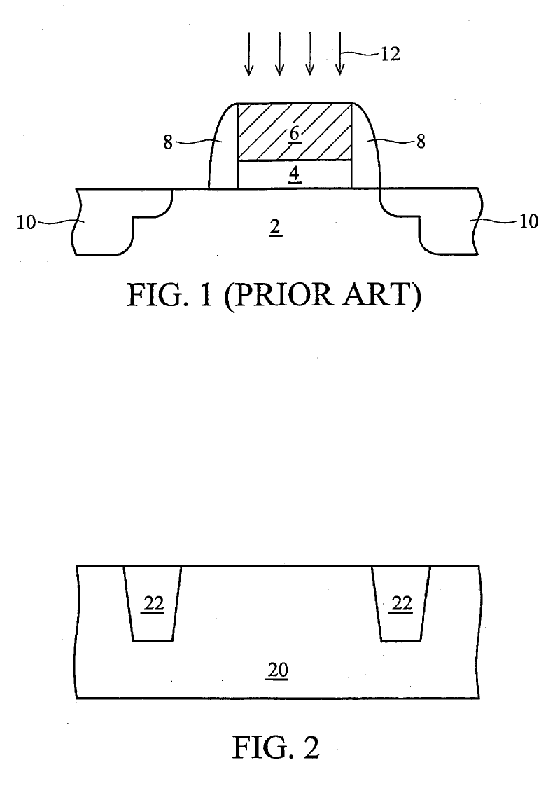

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The preferred embodiments are illustrated in FIGS. 2 through 6, wherein like reference numbers are used to designate like elements throughout the various views and illustrative embodiments of the present invention.

FIG. 2 illustrates the formation of shallow trench isolations (STI) 22 in a substrate 20. In the preferred embodiment, substrate 20 is a silicon substrate. In other embodiments, substrate 20 comprises other commonly used materials such as germanium, carbon, and/or their combinations. STIs 22 are formed in the substrate 20, preferably by etching shallow trenches in substrate 20, then filling the trenches with dielectric material, such as SiO₂ or HDP oxide. An implantation may be performed to dope substrate 20 with appropriate impurities to a desired concentration. In alternative embodiments, the impurity implantation may be performed before the formation of the STIs 22. In yet other embodiments, substrate 20 could be a silicon-on-insulator (SOI) substrate, as is well known in the art.

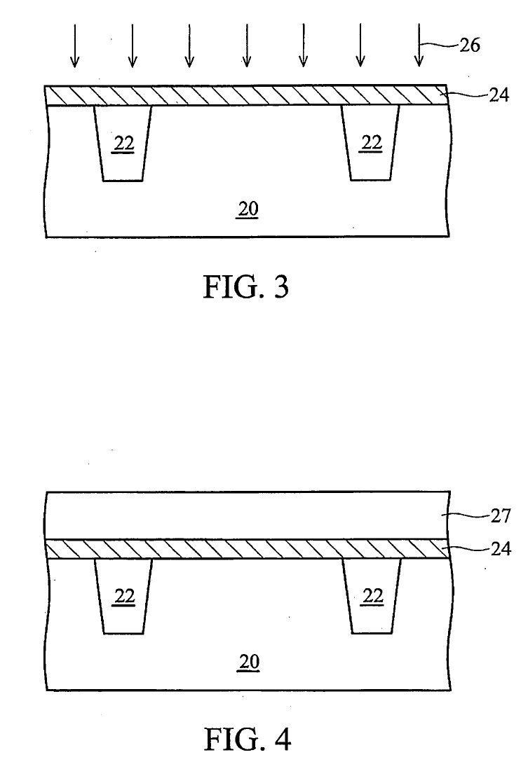

FIG. 3 illustrates a gate dielectric layer 24 deposited over the surface of the substrate 20 and STIs 22. In the preferred embodiment, the gate dielectric layer 24 has high k value. It may comprise materials such as HfO₂, HfSiOₓ, Ta₂O₅, SiO₂, SiON, and the like. In other embodiments, the gate dielectric layer 24 has a composite structure having a second dielectric layer over a first dielectric layer, wherein the first dielectric layer typically serves as a buffer layer. Both the first and second dielectric layer may comprise materials selected from the group consisting of HfO₂, HfSiOₓ, Ta₂O₅, SiO₂, SiON, and the like. The gate dielectric layer 24 has a preferred thickness of between about 5 Å and about 50 Å.

The dielectric layer 24 is then annealed using laser spike annealing (LSA), which is symbolized by arrows 26. Preferably, the laser spike annealing process is accomplished by scanning laser beam across a wafer or a chip so that areas are locally heated, and thus annealed, as the laser beam passes. Laser spike annealing uses a similar mechanism as laser thermal annealing (LTA) but with lower laser power. However, compared to conventional laser or spike annealing, laser spike annealing has the ability to treat each region in shorter time duration. The treatment time of the laser thermal annealing is about 1E-6 seconds to about 1E-2 seconds, while the treatment time of the laser spike annealing is between about 1E-9 and about 1E-3 seconds, wherein the treatment time is defined as the time duration between a laser beam entering a spot and exiting the spot.

Laser spike annealing can raise the temperature of a treated region to 1000° C. or higher in a very short period of time. In the preferred embodiment of the present invention, the annealing temperature is between about 1050° C. and about 1400° C., and treatment time is between about 1E-9 seconds to about 1E-3 seconds. In such as short time, agglomeration and diffusion are significantly reduced. High temperature annealing in a short time will put the dielectric layer 24 in a meta-stable state so that it is densified while being kept in an amorphous phase. The amorphous structure with high density results in better electrical performance. During annealing, the temperature of the substrate 20, which is typically lower than the surface temperature of the dielectric layer 24, needs to be kept under its melting temperature so that its crystal structure is not affected (the melting temperature of silicon is about 1410° C.). This is accomplished by controlling the annealing temperature of the dielectric layer 24 below the melting temperature of the substrate 20. Annealing may be performed in an ambient filled with gases such as, N₂, O₂, NH₃, H₂, D₂, N₂O, NO, and combinations thereof.

An advantageous feature of the preferred embodiment of the present invention is that laser beam treats dielectric layer 24 with no or very thin gate electrode layer to absorb laser energy, making it possible for using laser with shorter treatment time and less thermal budget. As known in the art, controlled laser power has sufficient energy density to densify dielectric layer 24 efficiently without melting the dielectric layer 24. The treatment time is short enough to eliminate diffusion but long enough to homogenize temperature in the material being annealed. Due to the short treating time, the underlying substrate temperature is raised less. During the entire annealing process, the temperature of the dielectric layer 24 is below its melting temperature, and the dielectric layer 24 is kept in amorphous state during and after annealing. This is particular important for substrates having low melting temperature, such as germanium, which has a melting temperature of about 937° C.

In an exemplary laser spike annealing process, a dielectric film formed of a 20 Å HfSiO layer over a SiO₂ layer is annealed. The annealing temperature is about 1250° C. The annealing is performed by using a laser power of about 0.2 KW/mm², which is generated by a laser beam having a wavelength of about 10 um. Treatment time is about 0.2 milliseconds. After the annealing, the dielectric film has an effective oxide thickness (EOT) of about 17.5 Å.

One side effect of conventional RTP or furnace annealing is that an undesired layer, often having a low-k value, is formed at the interface of the substrate 20 and the gate dielectric layer 24. With a laser spike annealing, the short annealing time makes undesired interface formation less likely to occur. Additionally, less heat is dissipated into the substrate 20. Therefore, laser spike annealing combined with lower laser power of laser has an effect of creating a high temperature gradient with a relatively sharp drop-off from the surface of the gate dielectric layer 24 into substrate 20. Therefore, substrate 20 is at a lower temperature than the gate dielectric layer 24. Diffusion in the substrate 20 is thus well controlled.

Since the dielectric layer 24 is blanket treated before the formation of the gate electrode, gate spacers and source/drain regions, the dielectric layer across the entire chip/wafer can be treated more uniformly. There is no need to treat different regions differently and thus the treatment process is simple. With no gate electrode to absorb laser energy, less laser energy is needed and controlling the temperature of the dielectric layer 24 is easier.

FIGS. 4 through 6 illustrate subsequent steps of the processes for forming a MOS transistor. After the laser spike annealing, a gate electrode layer 27 is formed over the gate dielectric 24, as shown in FIG. 4. The gate electrode layer 27 is preferably polysilicon, although it may be formed of metal, or a compound structure comprising metal, semiconductor, and/or metal silicide.

FIG. 5 illustrates the formation of gate electrode 28, gate dielectric 30, spacers 32 and source/drain regions 34. The gate electrode layer 27 and gate dielectric layer 24 are patterned, forming gate electrode 28 and gate dielectric 30, respectively. A pair of spacers 32 is formed along sidewalls of the gate dielectric 30 and gate electrode 28. Source/drain regions 34 are then formed, preferably by implanting desired dopant into substrate 20, or by recessing source/drain regions followed by epitaxially growing semiconductor materials with desired dopant in recesses. The formation of source/drain regions 34 is well known in the art and thus details are not repeated herein.

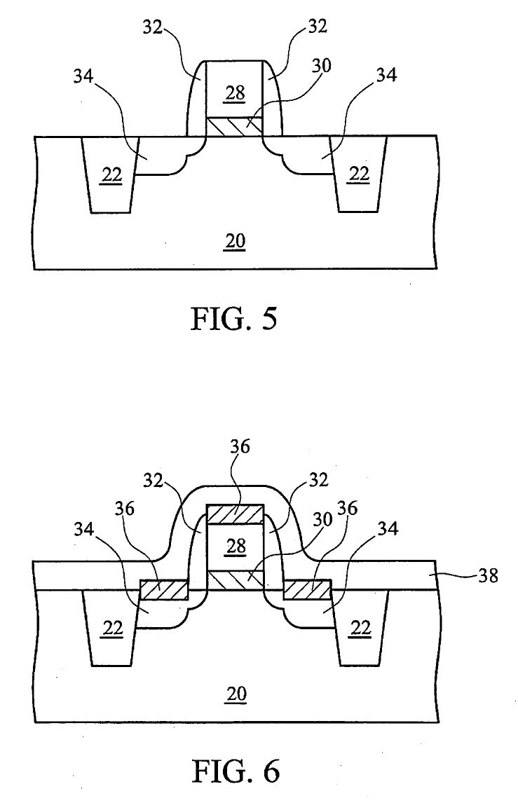

As illustrated in FIG. 6, metal silicides 36 are formed on source/drain regions 34 and gate electrode 28. In the preferred embodiment, silicides 36 are formed by first depositing a thin layer of metal, then annealing to form the silicides 36 between the deposited metal and the underlying exposed silicon regions. The un-reacted metal is then removed. A contact etch stop layer (CESL) 38 is then formed over the previously formed structure. CESL 38 acts as an etch stop layer to protect underlying regions from being over etched. It also provides stress to the device and thus enhances carrier mobility.

In an alternative embodiment of the present invention, laser spike annealing is performed after the formation of the gate electrode layer 27 but before patterning the gate electrode layer 27 and gate dielectric layer 24. In this embodiment, the gate electrode is preferably very thin with thickness of less than about 500 Å, more preferably between about 30 Å and about 200 Å. The energy of the laser beam will be partially absorbed by the gate electrode layer 27. However, a significant portion of the energy will penetrate the gate electrode layer 27 and reach the gate dielectric layer 24. The temperature in gate electrode layer 27 needs to be lower than its melting temperature. The thickness of gate electrode layer 27 should be carefully controlled for effective annealing treatment. Since the gate electrode absorbs a portion of the laser energy, potential issues arise. If too much laser power is used, the gate electrode may be melted. While if too little power is used, the densification effect for gate dielectric film may be poor. Therefore, thin gate electrode, which absorbs less energy than thick gate electrode, is preferred. The thinner the gate electrode is, the less energy is absorbed, and the easier it is to control the annealing process.

One application of the preferred embodiment of the present invention is the manufacture of capacitors. As known in the art, connecting a transistor's source and drain regions can form a capacitor. In the preferred embodiment, by connecting the source and drain regions 34 as shown in FIG. 6, the channel region of the transistor along with the source and drain regions 34 form one plate of the resulting capacitor, while the gate electrode 28 forms the other plate. Since the capacitance is proportional to the area of the gate dielectric 30, the capacitance is typically small. Therefore, it is advantageous to have a gate dielectric 30 having high k value since the capacitance is also proportional to k value of the gate dielectric 30, and this can be achieved by the preferred embodiments of the present invention.

Capacitance can also be increased by reducing the thickness of the dielectric layer, such as the gate dielectric 30 when the capacitor is formed of a transistor. However, the electric field in the dielectric layer increases when the thickness of the dielectric layer decreases. As a result, dielectric breakdown is more likely to occur. The preferred embodiment of the present invention provides a densified dielectric layer having higher density, less pores, and thus less likely to break down.

In alternative embodiments, a capacitor can be formed using other methods. For example, a first conductive plate is deposited. A dielectric layer is formed on the first metal plate. The dielectric layer is preferably laser spike annealed. A second conductive plate is then deposited on the dielectric layer.

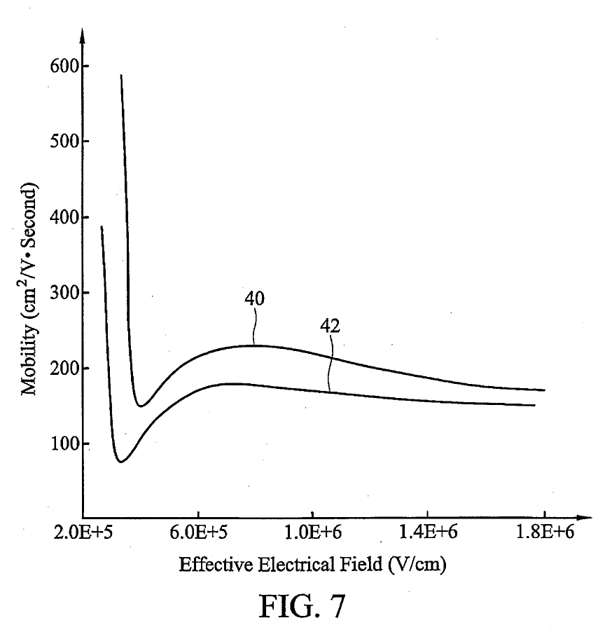

An advantageous feature of laser spike annealing can be found in FIG. 7, which illustrates carrier mobility as a function of effective electrical field in dielectric materials. Line 40 is obtained by measuring a dielectric film annealed at around 1200° C. using laser spike annealing. The dielectric film stack comprises about 20 Å HfSiO over SiO₂. Line 42 is obtained by measuring a similar film that is annealed using rapid thermal annealing at around 800° C. for about 12 seconds. After laser spike annealing, the dielectric film has an effective oxide thickness (EOT) of 17.5 Å, while after rapid thermal annealing, a comparable EOT of 17.8 Å is obtained on a similar film. However, the carrier mobility of the laser spike annealed film 40 is significantly higher than that of the film 42 thermally annealed.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of forming a semiconductor structure comprising the steps of:
providing a semiconductor substrate having a surface;
forming a gate dielectric layer on the surface of the semiconductor substrate;
performing a laser spike annealing to the gate dielectric layer; and
patterning the gate dielectric layer after laser spike annealing and thus forming at least a gate dielectric.

2. The method of claim 1 further comprising forming a gate electrode layer having a thickness of less than about 500 Å over the gate dielectric layer before the step of laser spike annealing.

3. The method of claim 1 further comprising the steps of:
forming a gate electrode layer after laser spike annealing;
patterning the gate dielectric layer and the gate electrode layer and thus forming a gate stack;
forming a spacer along an edge of the gate stack; and
forming a source region and a drain region, each substantially aligned with an edge of the gate stack.

4. The method of claim 3 further comprising connecting the source region and drain region to form a capacitor.

5. The method of claim 1 wherein the gate dielectric layer comprises a material selected from the group consisting essentially of HfO₂, HfSiOₓ, Ta₂O₅, SiO₂, SiON, and combinations thereof.

6. The method of claim 1 wherein the gate dielectric layer comprises a first layer and a second layer, wherein each of the first and second layers comprises a material selected from the group consisting essentially of HfO₂, HfSiOₓ, Ta₂O₅, SiO₂, SiON, and combinations thereof.

7. The method of claim 1 wherein the semiconductor substrate comprises a material selected from the group consisting essentially of silicon, germanium, carbon, and combinations thereof.

8. The method of claim 1 wherein the laser spike annealing is performed in an ambient comprising a gas selected from the group consisting essentially of N₂, O₂, NH₃, H₂, D₂, N₂O, NO, and combinations thereof.

9. The method of claim 1 wherein the temperature in the semiconductor substrate during the laser spike annealing is lower than a melting temperature of the semiconductor substrate.

10. The method of claim 1 wherein the laser spike annealing has a duration time of between about 1E-9 seconds and about 1E-3 seconds.

11. The method of claim 1 further comprising implanting an impurity into the semiconductor substrate before the forming the gate dielectric layer.

12. A method of forming a capacitor comprising:
forming a first conductive layer over a semiconductor substrate;
forming a dielectric layer on the first conductive layer;
laser spike annealing the dielectric layer; and
forming a second conductive layer on the first dielectric layer.

13. The method of claim 12 wherein the gate dielectric layer comprises a material selected from the group consisting essentially of HfO₂, HfSiOₓ, Ta₂O₅, SiO₂, SiON, and combinations thereof.

14. The method of claim 12 wherein the laser spike annealing has a duration time of between about 1E-9 seconds and about 1E-3 seconds.

15. The method of claim 12 wherein:
the first conductive layer comprises a gate electrode in a transistor; and
the second conductive layer comprises a channel region of the transistor.
